(19) United States
(12) Patent Application Publication
(10) Pub. No.: US 2025/0246498 A1
(43) Pub. Date: Jul. 31, 2025

(54) HEAT TRANSFER MEMBER

(71) Applicant: DENSO CORPORATION, Kariya-city (JP)

(72) Inventors: Takahito SHIBATA, Kariya-city (JP); Kimio KOHARA, Kariya-city (JP); Yoichiro KAWAMOTO, Kariya-city (JP)

(21) Appl. No.: 19/184,616

(22) Filed: Apr. 21, 2025

Related U.S. Application Data
(63) Continuation of application No. PCT/JP2023/037151, filed on Oct. 13, 2023.

(30) Foreign Application Priority Data
Oct. 28, 2022 (JP) 2022-173289

(51) Int. Cl. H01L 23/367; H01L 23/373; H01L 23/427; H05K 7/20

(52) U.S. Cl. CPC H01L 23/367; H01L 23/427; H05K 7/203; H05K 7/20327; H01L 23/3736

(57) ABSTRACT

A heat transfer member is applied to a cooling apparatus that cools a cooling target in a state where the cooling target is immersed in a refrigerant in a liquid phase. The refrigerant is an electrically insulating fluorinated refrigerant. The heat transfer member achieves a heat flux q of 300 kW/m² or more when a degree of superheat dT of the refrigerant is 10 K, on a boiling curve having a horizontal axis representing the degree of superheat dT of the refrigerant and a vertical axis representing the heat flux q. The degree of superheat dT is defined as a value obtained by subtracting a saturation temperature Ts of the refrigerant from a temperature Tw of the heat transfer member. The heat flux q is defined as the amount of heat transferred per unit area from the heat transfer member to the refrigerant.

### CROSS REFERENCE TO RELATED APPLICATIONS

This application is a continuation application of International Patent Application No. PCT/JP2023/037151 filed on Oct. 13, 2023, which designated the U.S. and claims the benefit of priority from Japanese Patent Application No. 2022-173289 filed on Oct. 28, 2022. The entire disclosures of all of the above applications are incorporated herein by reference.

### TECHNICAL FIELD

The present disclosure relates to a heat transfer member applied to a boiling-cooling type cooling apparatus.

### BACKGROUND

Previously, there has been proposed a boiling-cooling type cooling apparatus that cools a cooling target, such as an electronic component, which generates heat during operation, by immersing the cooling target in a liquid-phase refrigerant (in other words, a refrigerant liquid). In the boiling-cooling type cooling apparatus, the refrigerant liquid is boiled by the heat generated by the cooling target, and the latent heat of vaporization during the vaporization of the refrigerant liquid is utilized to cool the cooling target. Furthermore, the previously proposed cooling apparatus includes a heat transfer member, which promotes heat transfer from the cooling target to the refrigerant.

### SUMMARY

This section provides a general summary of the disclosure, and is not a comprehensive disclosure of its full scope or all of its features.

According to one aspect of the present disclosure, there is provided a heat transfer member to be applied to a cooling apparatus that is configured to cool a cooling target in a state where the cooling target is immersed in a refrigerant in a liquid phase while the heat transfer member is configured to promote heat transfer from the cooling target to the refrigerant. The cooling target is an electronic device. The refrigerant is an electrically insulating fluorinated refrigerant, a boiling point of which is equal to or lower than 100 degrees Celsius. The refrigerant is exposed to an atmosphere. The heat transfer member is configured to achieve a heat flux q of 300 kW/m² or more when a degree of superheat dT of the refrigerant is 10 K, on a boiling curve having a horizontal axis representing the degree of superheat dT of the refrigerant and a vertical axis representing the heat flux q.

According to another aspect of the present disclosure, there is provided a heat transfer member to be applied to a cooling apparatus that is configured to cool a cooling target in a state where the cooling target is immersed in a refrigerant in a liquid phase while the heat transfer member is configured to promote heat transfer from the cooling target to the refrigerant. The heat transfer member includes a refrigerant side surface that is configured to contact the refrigerant and has a boiling promotion surface, which is configured to promote boiling of the refrigerant. In a roughness curve of the boiling promotion surface, each of a plurality of portions, each formed between two adjacent peaks among a plurality of peaks, is defined as a hole; a distance between the two adjacent peaks is defined as a hole width Gw; a distance between a line connecting between the two adjacent peaks and a bottom of the hole is defined as a hole depth Gd; a value, which is obtained by dividing the hole depth Gd by the hole width Gw, is defined as a hole aspect ratio Gd/Gw; and a number of holes, which are present per unit length among a plurality of holes formed respectively by the plurality of portions, is defined as a hole number Ng. The hole number Ng of the holes, each having the hole aspect ratio Gd/Gw equal to or larger than 0.01, present per 1 mm is equal to or larger than 9.

According to another aspect of the present disclosure, there is provided a manufacturing method of the heat transfer member which includes a boiling promotion surface formation step in which a boiling promotion surface configured to promote boiling of the refrigerant is formed by shot blasting on at least a part of a refrigerant side surface of the heat transfer member which is configured to contact the refrigerant.

### BRIEF DESCRIPTION OF DRAWINGS

The drawings described herein are for illustrative purposes only of selected embodiments and not all possible implementations, and are not intended to limit the scope of the present disclosure.

FIG. 1 is a schematic diagram showing an overall structure of a cooling apparatus according to one embodiment.

FIG. 2 is a schematic cross-sectional view taken along line II-II in FIG. 1, showing a cooler according to the one embodiment.

FIG. 3 is a schematic cross-sectional view taken along line III-III in FIG. 2, showing a heat transfer member according to the one embodiment.

FIG. 4 is an external perspective view of the heat transfer member according to the one embodiment.

FIG. 5 is an enlarged view as seen in a direction of arrow V in FIG. 4.

FIG. 6 is an explanatory diagram for explaining holes of a boiling promotion surface according to the one embodiment.

FIG. 7 is a boiling curve of the heat transfer member according to the one embodiment.

FIG. 8 is a graph showing a relationship between a hole aspect ratio and a cumulative value of the number of holes Ng according to the one embodiment.

FIG. 9 is a graph showing a relationship between a hole width and a hole aspect ratio according to the one embodiment.

FIG. 10 is an external perspective view of a heat transfer member according to another embodiment.

### DETAILED DESCRIPTION

Previously, there has been proposed a boiling-cooling type cooling apparatus that cools a cooling target, such as an electronic component, which generates heat during operation, by immersing the cooling target in a liquid-phase refrigerant (in other words, a refrigerant liquid). In the boiling-cooling type cooling apparatus, the refrigerant liquid is boiled by the heat generated by the cooling target, and the latent heat of vaporization during the vaporization of the refrigerant liquid is utilized to cool the cooling target.

Furthermore, the previously proposed cooling apparatus includes: a heat transfer member, which promotes heat transfer from the cooling target to the refrigerant; and a circulation pump, which pumps the refrigerant liquid toward the heat transfer member. The heat transfer member of the previously proposed cooling apparatus includes a finned portion, which forms a plurality of fins for increasing a contact surface area between the heat transfer member and the refrigerant liquid.

Furthermore, in the previously proposed cooling apparatus, the refrigerant liquid, which is pumped from the circulation pump, is made to collide with the heat transfer member, thereby expelling gas-phase refrigerant droplets (in other words, gas bubbles) generated within the grooves each formed between adjacent fins. As a result, the previously proposed cooling apparatus aims to enhance the cooling performance for cooling the cooling target by promoting the boiling of the refrigerant in the vicinity of the heat transfer member.

However, in the previously proposed cooling apparatus, a flow velocity and a flow direction of the refrigerant liquid pumped from the circulation pump, as well as a depth dimension and a width dimension of each fin of the heat transfer member, are determined to effectively expel the bubbles present in the grooves.

Therefore, in the previously proposed cooling apparatus, when the operating conditions change to change the flow velocity and/or the flow direction of the refrigerant liquid pumped from the circulation pump, it may become difficult to effectively expel the bubbles present in the grooves using the refrigerant liquid pumped from the circulation pump. In other words, in the previously proposed cooling apparatus, when the operating conditions change, the heat transfer performance of the heat transfer member may deteriorate, potentially leading to a decrease in the cooling performance of the cooling apparatus.

According to one aspect of the present disclosure, there is provided a heat transfer member to be applied to a cooling apparatus that is configured to cool a cooling target in a state where the cooling target is immersed in a refrigerant in a liquid phase while the heat transfer member is configured to promote heat transfer from the cooling target to the refrigerant.

The cooling target is an electronic device. The refrigerant is an electrically insulating fluorinated refrigerant, a boiling point of which is equal to or lower than 100 degrees Celsius. The refrigerant is exposed to an atmosphere. The heat transfer member is configured to achieve a heat flux q of 300 kW/m² or more when a degree of superheat dT of the refrigerant is 10 K, on a boiling curve having a horizontal axis representing the degree of superheat dT of the refrigerant and a vertical axis representing the heat flux q.

The degree of superheat dT is defined as a value obtained by subtracting a saturation temperature Ts of the refrigerant from a temperature Tw of the heat transfer member. The heat flux q is defined as the amount of heat transferred per unit area from the heat transfer member to the refrigerant.

Accordingly, on the boiling curve, when the degree of superheat dT reaches 10 K, the heat flux q reaches 300 kW/m², allowing high heat transfer performance to be exhibited regardless of the operating conditions of the cooling apparatus provided with the heat transfer member. As a result, the cooling apparatus provided with the heat transfer member can stably exhibit the high cooling performance.

Furthermore, according to another aspect of the present disclosure, there is provided a heat transfer member to be applied to a cooling apparatus that is configured to cool a cooling target in a state where the cooling target is immersed in a refrigerant in a liquid phase while the heat transfer member is configured to promote heat transfer from the cooling target to the refrigerant. The heat transfer member includes a refrigerant side surface that is configured to contact the refrigerant and has a boiling promotion surface, which is configured to promote boiling of the refrigerant.

In a roughness curve of the boiling promotion surface, each of a plurality of portions, each formed between two adjacent peaks among a plurality of peaks, is defined as a hole. Furthermore, a distance between the two adjacent peaks is defined as a hole width Gw. Also, a distance between a line connecting between the two adjacent peaks and a bottom of the hole is defined as a hole depth Gd. Additionally, a value, which is obtained by dividing the hole depth Gd by the hole width Gw, is defined as a hole aspect ratio Gd/Gw. In addition, a number of holes, which are present per unit length among a plurality of holes formed respectively by the plurality of portions, is defined as a hole number Ng. The hole number Ng of the holes, each having the hole aspect ratio Gd/Gw equal to or larger than 0.01, present per 1 mm is equal to or larger than 9.

Accordingly, since the hole number of the holes each having the hole aspect ratio Gd/Gw equal to or larger than 0.01, present per 1 mm is equal to or larger than 9 at the refrigerant side surface, high heat transfer performance can be exhibited regardless of the operating conditions of the cooling apparatus provided with the heat transfer member, as will be described in an embodiment later. As a result, the cooling apparatus provided with the heat transfer member can stably exhibit the high cooling performance.

Furthermore, according to another aspect of the present disclosure, there is provided a manufacturing method of a heat transfer member to be applied to a cooling apparatus that is configured to cool a cooling target in a state where the cooling target is immersed in a refrigerant in a liquid phase while the heat transfer member is configured to promote heat transfer from the cooling target to the refrigerant.

The manufacturing method includes a boiling promotion surface formation step in which a boiling promotion surface configured to promote boiling of the refrigerant is formed by shot blasting on at least a part of a refrigerant side surface of the heat transfer member which is configured to contact the refrigerant.

Accordingly, the boiling promotion surface can be formed on the heat transfer member. Therefore, it is possible to provide the manufacturing method of the heat transfer member capable of exhibiting the high heat transfer performance regardless of the operating conditions of the cooling apparatus provided with the heat transfer member.

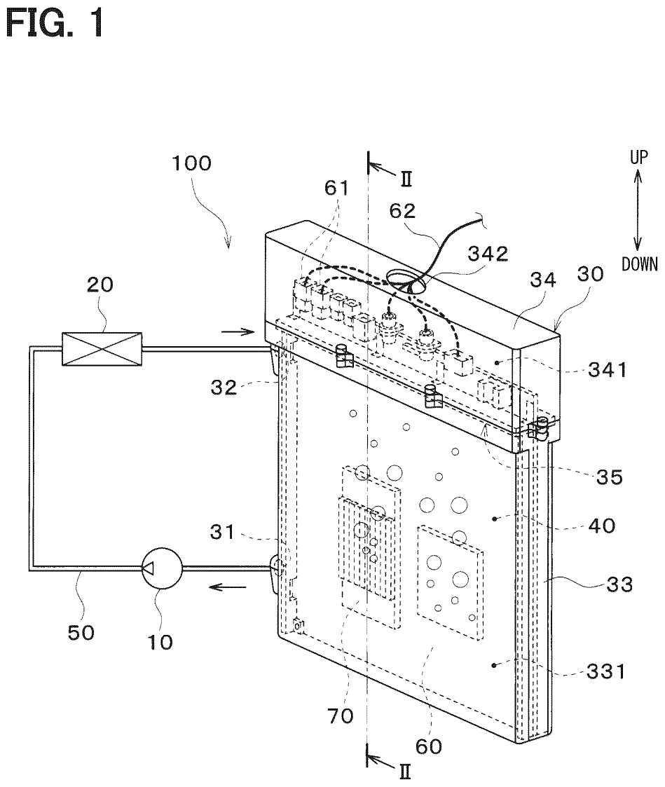

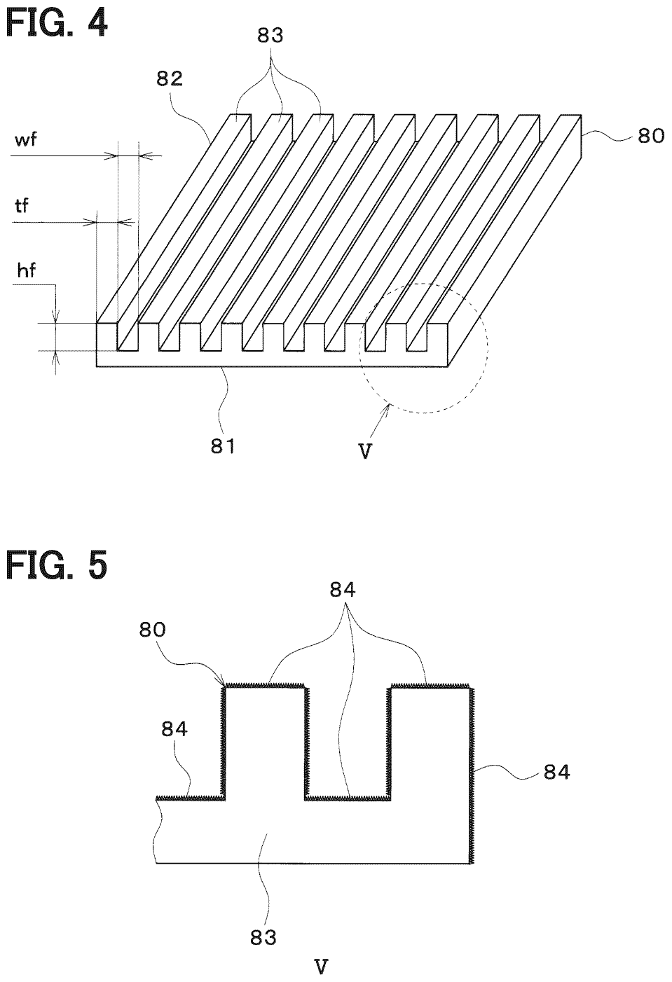

Hereinafter, one embodiment of the present disclosure will be described with reference to FIGS. 1 to 9. In the present embodiment, a heat transfer member (also referred to as a heat sink) 80 is applied to a cooler 30 of a cooling apparatus 100. The cooling apparatus 100 of the present embodiment is a boiling cooling-type cooling apparatus that is configured to cool a heat-generating device 70, which is a cooling target, in a state where the heat-generating device 70 is immersed in a refrigerant liquid 40 which is a refrigerant in a liquid phase.

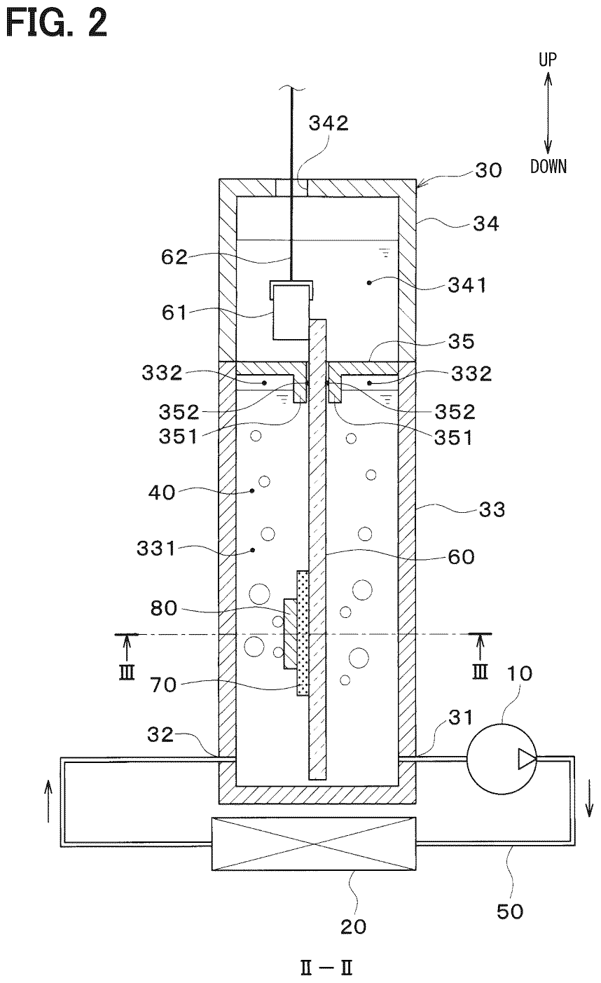

As shown in FIGS. 1 and 2, the cooling apparatus 100 includes a circulation pump 10, a radiator 20 and the cooler 30. More specifically, the cooling apparatus 100 is formed by installing the circulation pump 10, the radiator 20 and the cooler 30 in a circulation circuit 50 that is configured to circulate the refrigerant liquid 40. An upward arrow and a downward arrow in FIGS. 1 and 2 respectively indicate an upward direction and a downward direction in the vertical direction at the cooler 30 which is properly positioned.

First, the circulation pump 10 is a pumping device that suctions and pressurizes the refrigerant liquid 40 discharged from a circulation outlet 31 of the cooler 30. The circulation pump 10 is an electrically operated liquid pump that operates upon receiving an electric power. A magnet pump, a canned pump or the like, in which at least a part of an electric motor (serving as a drive device) is sealed against the refrigerant liquid 40, may be used as the circulation pump 10.

In the present embodiment, an electrically insulating fluorinated refrigerant with a boiling point of 100° C. or lower is used as the refrigerant. The electrically insulating fluorinated refrigerant is a refrigerant that excels in electrical insulation, heat transfer properties, and stability. More specifically, in the present embodiment, Novec (a product name and registered trademark of 3M Company), which has a hydrofluoroether (HFE) structure, is used as the refrigerant. For example, Opteon (a product name and registered trademark of Chemours-Mitsui Fluoroproducts Co., Ltd.), Galden (a product name and registered trademark of Solvay S.A.), AsahiKlin (a product name and registered trademark of AGC Inc.), Solble (a product name of SOLVEX Co., Ltd.), or the like may also be used as the refrigerant.

A refrigerant inlet of the radiator 20 is connected to a discharge outlet of the circulation pump 10. The radiator 20 is a heat releasing heat exchanger that is configured to release the heat of the refrigerant liquid 40 to the atmosphere by exchanging the heat between the refrigerant liquid 40 and the atmosphere. The radiator 20 limits a temperature increase of the refrigerant liquid 40, which is circulating through the circulation circuit 50, by releasing the heat of the refrigerant liquid 40 into the atmosphere, thereby maintaining a subcooled state of the refrigerant liquid 40.

A circulation inlet 32 of the cooler 30 is connected to a refrigerant outlet of the radiator 20. The cooler 30 is configured to cool the heat-generating device 70 which is the cooling target. As shown in a cross-sectional view of FIG. 2, the cooler 30 includes a cooling tank 33, a liquid storage tank 34 and a partition member 35. The cooling tank 33, the liquid storage tank 34 and the partition member 35 can be formed from a resin material or a metal material.

The cooling tank 33 is formed in a form of a container that is shaped in a rectangular parallelepiped form and has an opening at a top surface thereof. A receiving space 331, which receives a lower portion of an electronic circuit board 60, is formed at an inside of the cooling tank 33. The cooling tank 33 includes: the circulation inlet 32, which is configured to receive the refrigerant liquid 40 outputted from the radiator 20; and the circulation outlet 31, which is configured to output the refrigerant liquid 40 toward a suction inlet of the circulation pump 10. Therefore, the receiving space 331 stores the refrigerant liquid 40.

The electronic circuit board 60 is an electrical circuit board formed as a so-called rigid printed circuit board. A plurality of electronic devices, including the heat-generating device 70, are installed on the electronic circuit board 60. A portion of the electronic circuit board 60, on which the plurality of electronic devices, including the heat-generating device 70, are installed, becomes a portion of the electronic circuit board 60 immersed in the refrigerant liquid 40 when the electronic circuit board 60 is received in the receiving space 331. Accordingly, the heat-generating device 70 is received in an inside space of the cooling tank 33 in a state where the heat-generating device 70 is immersed in the refrigerant liquid 40.

The heat-generating device 70 is an electronic device referred to as a large-scale integrated circuit. More specifically, the heat-generating device 70 is a central processing unit of a computer. The heat-generating device 70 generates the heat during the operation thereof. The heat-generating device 70 tends to experience a deterioration in performance, such as computational capacity, when the heat-generating device 70 becomes hot. Therefore, in the cooling apparatus 100 of the present embodiment, the heat-generating device 70 is cooled to limit the deterioration in the performance.

The heat-generating device 70 is shaped in a rectangular flat plate form. The heat-generating device 70 is joined to the electronic circuit board 60 by soldering. Furthermore, the heat transfer member 80 is attached to a surface of the heat-generating device 70, which is opposite to a surface of the heat-generating device 70 that is joined to the electronic circuit board 60. The heat transfer member 80 is a heat transfer portion that is configured to promote heat transfer from the heat-generating device 70 to the refrigerant. A structure of the heat transfer member 80 will be descried later in detail.

Here, a boiling point of the refrigerant liquid 40 of the present embodiment is set to a value lower than a generated heat temperature that is reached when the heat-generating device 70 generates the heat. Therefore, the cooler 30 performs boiling cooling, in which the refrigerant liquid 40 is boiled by the heat generated from the heat-generating device 70, and the heat-generating device 70 is cooled by utilizing the latent heat of vaporization during the evaporation of the refrigerant liquid 40.

Furthermore, in the cooler 30 of the present embodiment, subcooled boiling occurs, where the refrigerant liquid 40 in a region distant from the heat-generating device 70 remains as a subcooled liquid at a temperature below the boiling point of the refrigerant liquid 40, while the refrigerant liquid 40 in contact with the heat transfer member 80 attached to the heat-generating device 70 boils.

Bubbles of refrigerant gas, which are generated by the boiling of the refrigerant liquid 40 in contact with the heat transfer member 80, are cooled and condensed in the subcooled liquid. Bubbles, which cannot be condensed in the subcooled liquid, are accumulated in an upper portion of the receiving space 331, thereby forming a refrigerant gas layer 332. The refrigerant gas layer 332 contains not only the refrigerant in the gas phase but also a dissolved gas (specifically, air) that was previously dissolved in the refrigerant liquid 40. Of course, when all the bubbles are condensed, a volume of the refrigerant gas layer 332 becomes zero.

The liquid storage tank 34 is formed in a form of a container that is shaped in a rectangular parallelepiped form and has an opening at a bottom surface thereof. The liquid storage tank 34 is positioned on an upper side of the cooling tank 33. The opening at the upper part of the cooling tank 33 and the opening at the lower part of the liquid storage tank 34 are formed in shapes that fit each other.

The cooling tank 33 and the liquid storage tank 34 are integrated together by means such as bolts in a state where the opening of the cooling tank 33 and the opening of the liquid storage tank 34 are aligned with each other. A seal member (not shown), such as a gasket, is interposed between the opening of the cooling tank 33 and the opening of the liquid storage tank 34. Therefore, the refrigerant inside the cooler 30 does not leak to the outside through a gap between the opening of the cooling tank 33 and the opening of the liquid storage tank 34.

A storage space 341, which stores the refrigerant liquid 40, is formed at the inside of the liquid storage tank 34. An upper surface of the liquid storage tank 34 has an opening 342, which extends through a wall of the liquid storage tank 34 to communicate between the inside and the outside of the liquid storage tank 34. As a result, the atmospheric gas (air) from the atmosphere can flow into the storage space 341 through the opening 342. In other words, in the cooler 30, the refrigerant is exposed to the atmosphere.

An upper portion of the electronic circuit board 60 is received in the storage space 341. A connector 61 is installed to the upper portion of the electronic circuit board 60. The connector 61 is an electrical connection portion to which an electrical cable 62 is connected. The electrical cable 62 includes: power lines, which serve as a transmission path for the electric power; and signal lines, which serve as a transmission path for electrical signals. The electrical cable 62, which is connected to the connector 61, is routed from the opening 342 to the outside of the cooler 30.

The partition member 35 partitions between the receiving space 331 of the cooling tank 33 and the storage space 341 of the liquid storage tank 34. The partition member 35 is shaped generally in a flat plate form. An outer periphery of the partition member 35 is shaped in a form that fits the opening of the cooling tank 33. The partition member 35 is fixed to the opening of the cooling tank 33 by means such as bolting, press-fitting, or adhesive bonding. A portion of the partition member 35, which extends in the horizontal direction, forms a bottom surface of the storage space 341.

In addition, a slit hole, through which the electronic circuit board 60 is inserted, is formed through a center portion of the partition member 35. A support portion 351, which is shaped to project toward the receiving space 331, is formed around the slit hole. The electronic circuit board 60 is clamped by the support portion 351 and is thereby supported such that the electronic circuit board 60 does not come into contact with an inner wall surface of the cooling tank 33. The support portion 351 also functions as a gas layer retention portion, which retains the refrigerant gas layer 332 generated in the receiving space 331.

Furthermore, a communicating portion 352 is formed between the partition member 35 and the electronic circuit board 60. The communicating portion 352 is a refrigerant passage that communicates between the receiving space 331 of the cooling tank 33 and the storage space 341 of the liquid storage tank 34.

As discussed above, since the liquid storage tank 34 has the opening 342, the atmospheric pressure is applied to the refrigerant in the storage space 341. Therefore, when a volume of the refrigerant in the cooling tank 33 fluctuates due to the boiling or the condensation of the refrigerant in the receiving space 331, the refrigerant liquid 40 moves between the receiving space 331 and the storage space 341 through the communicating portion 352.

As discussed above, by allowing the refrigerant liquid 40 to move between the receiving space 331 and the storage space 341 through the communicating portion 352, the cooling tank 33 is always supplied with the refrigerant liquid 40 for immersing the heat-generating device 70.

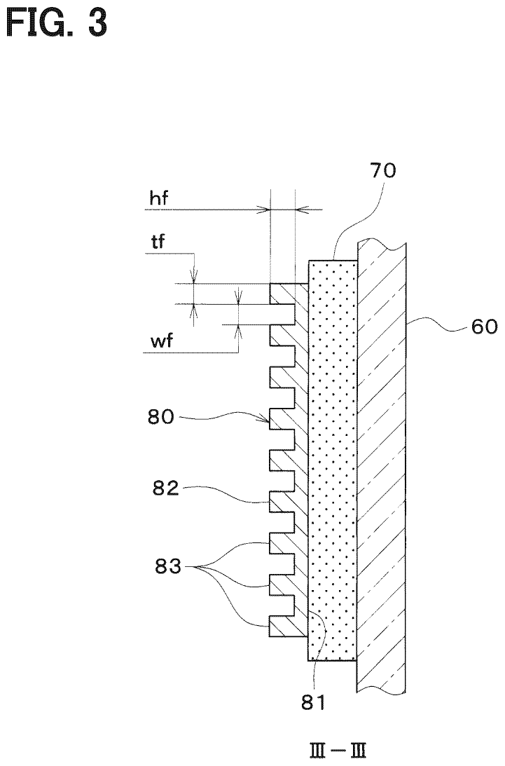

Next, the heat transfer member 80 will be described with reference to FIGS. 3 to 5. The heat transfer member 80 is made of a material with excellent heat transfer properties and is shaped in a flat plate form. The heat transfer member 80 of the present embodiment is made of metal, such as aluminum or copper. An outer surface of the heat transfer member 80 is broadly divided into a heat-generating body side surface 81 and a refrigerant side surface 82.

The heat-generating body side surface 81 is a flat surface of the outer peripheral surface of the heat transfer member 80 that contacts the heat-generating device 70. The heat-generating body side surface 81 serves as a contact surface. The heat-generating body side surface 81 is joined by means such as soldering to a flat surface of the heat-generating device 70 which is opposite to the surface of the heat-generating device 70 joined to the electronic circuit board 60.

More specifically, in the present embodiment, the heat-generating device 70 and the electronic circuit board 60 are joined by reflow soldering, in which paste solder is printed on at least one of the bonding surfaces of the heat-generating device 70 and the electronic circuit board 60, and the printed solder is heated and melted in a reflow oven. Accordingly, the heat-generating device 70 and the electronic circuit board 60 can be joined over an entire area of the bonding surfaces.

The refrigerant side surface 82 is a surface that is configured to contact the refrigerant liquid 40. Therefore, the refrigerant side surface 82 is a surface of the outer peripheral surface of the heat transfer member 80, which is other than the heat-generating body side surface 81. In other words, the refrigerant side surface 82 includes not only the surface of the outer peripheral surface of the heat transfer member 80, which is opposed to the heat-generating body side surface 81, but also surfaces that intersects with the heat-generating body side surface 81.

A finned portion 83 is formed on the surface of the refrigerant side surface 82, which is opposed to the heat-generating body side surface 81. The finned portion 83 is a surface area expansion portion that increases a surface area of the refrigerant side surface 82 and promotes heat transfer from the heat-generating device 70 to the refrigerant. The finned portion 83 of the present embodiment is formed on the refrigerant side surface 82, which is opposed to the heat-generating body side surface 81 among the outer peripheral surface of the heat transfer member 80.

The finned portion 83 of the present embodiment is formed by a plurality of grooves, each of which has a rectangular cross-section and is provided on the refrigerant side surface 82 that is opposed to the heat-generating body side surface 81. The plurality of grooves extend in the up-down direction and are parallel to each other. Therefore, the finned portion 83 of the present embodiment forms so-called straight fins.

Here, a height dimension, which is measured from a bottom surface of a groove of each fin formed between the corresponding adjacent grooves, is defined as a fin height hf. Additionally, a thickness dimension of each fin, which corresponds to a distance between two adjacent grooves, is defined as a fin thickness tf. Furthermore, a value, which is obtained by dividing the fin height hf by the fin thickness tf, is defined as a fin aspect ratio hf/tf. In addition, a distance between two adjacent fins is defined as a fin interval wf.

In the present embodiment, the fin aspect ratio hf/tf is set to 1.3 or larger. As a result, the heat transfer member 80 of the present embodiment expands the surface area of the refrigerant side surface 82 by 1.8 times or more compared to a heat transfer member without the finned portion 83. Also, in the present embodiment, the fin interval wf is set to 0.2 mm or larger. As a result, retention of the bubbles of the refrigerant gas, which is formed by boiling on the finned portion 83, in the grooves is limited.

Furthermore, at least a part of the refrigerant side surface 82 in the present embodiment has a boiling promotion surface 84 formed on it. The boiling promotion surface 84 is a surface on the refrigerant side surface 82 that has been roughened by a roughening treatment to promote the boiling of the refrigerant liquid 40. More specifically, as shown in FIG. 5, the boiling promotion surface 84 is formed on: surfaces, which form tops of the finned portion 83 on the refrigerant side surface 82; lateral surfaces of each adjacent two of the fines, which are opposed to each other; surfaces that form the bottoms of the grooves, and side surfaces of the outer peripheral surface of the heat transfer member 80.

It is desirable for the boiling promotion surface 84 to have a surface area larger than that of the heat-generating body side surface 81 and to occupy 50% or more of a surface area of the refrigerant side surface 82. Of course, the boiling promotion surface 84 may be formed over the entire surface area of the refrigerant side surface 82. Additionally, it is desirable for the boiling promotion surface 84 to be formed on 50% or more of the finned portion 83.

Next, the structure of the boiling promotion surface 84 will be described in detail. As described above, the boiling promotion surface 84 is the surface on the refrigerant side surface 82 that has been roughened by the roughening treatment. In the heat transfer member 80, when the refrigerant side surface 82 is roughened by the roughening treatment, a site is created where the boiling begins at the time of boiling the refrigerant liquid 40. This enables the promotion of the boiling.

Therefore, in the boiling promotion surface 84 of the present embodiment, the roughening treatment is performed such that a surface roughness Rz of the boiling promotion surface 84 satisfies the following equation F1.

1≤Rz≤150 (F1)

The surface roughness Rz of the present embodiment is an index known as the ten-point average roughness.

More specifically, the surface roughness Rz is determined as follows. First, a section stretching over a reference length in a predetermined direction from the roughness curve is extracted. Then, it is calculated as the sum of the average absolute height values of the highest five peak tops and the average absolute height values of the lowest five valley bottoms within the extracted section, expressed in micrometers (μm).

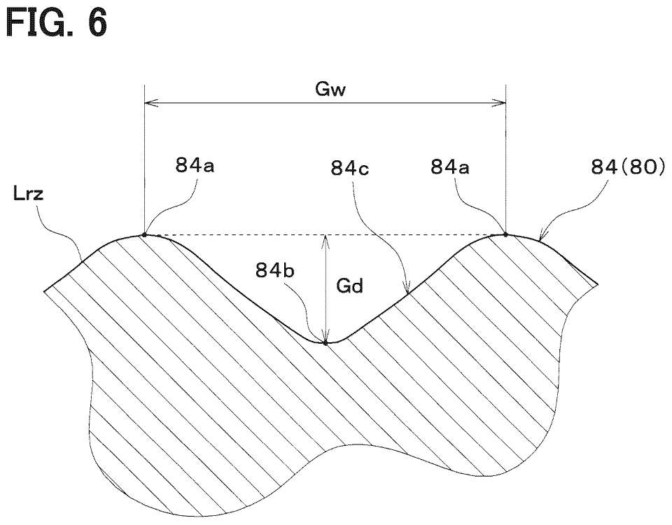

The roughness curve is a curve obtained by removing wavelength components longer than a predetermined cutoff wavelength from the cross-sectional profile along a section perpendicular to the flat surface, which corresponds to the cross-sectional profile along the measurement direction of the surface. In FIG. 6, a bold line represents a roughness curve Lrz on the boiling promotion surface 84 of the present embodiment.

Furthermore, in the present embodiment, as shown in FIG. 6, in the roughness curve of the boiling promotion surface 84, each of a plurality of recesses (serving as a plurality of portions), each formed between two adjacent peaks 84a among a plurality of peaks 84a, is defined as a hole 84c. Additionally, a distance between the two adjacent peaks 84a is defined as a hole width Gw. Also, a distance between a line connecting between the two adjacent peaks 84a and a valley bottom 84b of the hole 84c located between the two adjacent peaks 84a is defined as a hole depth Gd. Additionally, a value, which is obtained by dividing the hole depth Gd by the hole width Gw, is defined as a hole aspect ratio Gd/Gw. Additionally, the number of holes 84c, which are present per unit length (1 mm in the present embodiment), is defined as the hole number Ng (also referred to as the number of holes Ng).

In the boiling promotion surface 84 of the present embodiment, the roughening treatment is performed such that the hole number Ng of the holes 84c, which satisfy the following equation F2, satisfies the following equation F3, ensuring effective boiling promotion.

Gd/Gw≥0.01 (F2)

Ng≥9 (F3)

That is, in the boiling promotion surface 84 of the present embodiment, the roughening treatment is performed such that: the hole number Ng of the holes 84c, each having the hole aspect ratio Gd/Gw equal to or larger than 0.01, present per 1 mm is equal to or larger than 9. Additionally, the hole aspect ratio Gd/Gw may be equal to or smaller than 0.4.

Furthermore, the hole width Gw may be determined so as to satisfy the following equation F4.

315 μm≥Gw≥1.7 μm (F4)

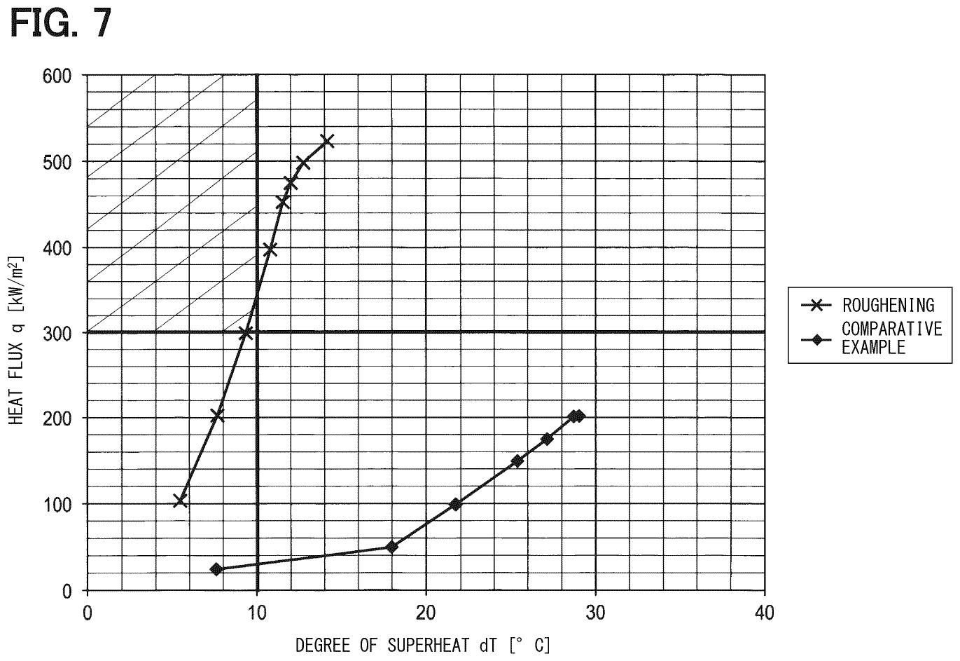

By the roughening treatment described above, the heat transfer member 80 of the present embodiment achieves a heat flux q of 300 kW/m² or more when a degree of superheat dT of the refrigerant is 10 K, on a boiling curve having a horizontal axis representing the degree of superheat dT of the refrigerant and a vertical axis representing the heat flux q, as shown in FIG. 7. The degree of superheat dT is defined as a value obtained by subtracting a saturation temperature Ts of the refrigerant liquid 40 from a temperature Tw of the heat transfer member 80. The heat flux q is defined as the amount of heat transferred per unit time from the heat transfer member 80 to the refrigerant liquid 40.

Additionally, in FIG. 7, a boiling curve of a heat transfer member without the boiling promotion surface 84, i.e., a heat transfer member without the roughening treatment, is also shown as a comparative example.

Next, a manufacturing method for manufacturing the heat transfer member 80 of the present embodiment will be described. First, in a material preparation step, a material for the heat transfer member 80, in which the aforementioned finned portion 83 is formed, is prepared. In the material preparation step, the material, in which the finned portion 83 is formed on a flat plate material, such as aluminum or copper by press working or cutting, may be prepared.

In a boiling promotion surface forming step, the boiling promotion surface 84 is formed on the material prepared in the material preparation step. In the boiling promotion surface forming step, the boiling promotion surface 84 is formed by shot blasting. The shot blasting is a processing method in which fine alumina-based blasting media are sprayed onto the material and made to collide with it, thereby forming small holes on a surface of the material and roughening the surface. The material for the blasting media can be selected from iron, stainless steel, zinc, ceramics, resin, and the like.

In the boiling promotion surface forming step of the present embodiment, the blasting media are sprayed onto the finned portion 83 in a direction perpendicular to the heat-generating body side surface 81. As a result, the surfaces, which form the tops of the finned portion 83 on the refrigerant side surface 82, and the surfaces, which form the bottoms of the grooves, become the boiling promotion surface 84. Additionally, the blasting media are sprayed onto the heat transfer member 80 from four horizontal directions which are parallel to the heat-generating body side surface 81. As a result, the side surfaces of the outer peripheral surface of the heat transfer member 80 become the boiling promotion surface 84. By spraying the blasting media, which are sufficiently smaller than the fin interval wf, onto the finned portion 83 from the various directions, the entire surface of the finned portion 83 can be roughened. As a result, the entire surface of the finned portion 83 becomes the boiling promotion surface 84.

Next, an operation of the cooling apparatus 100 of the present embodiment will be described. First, when the circulation pump 10 is activated, it suctions and pumps the refrigerant liquid 40 that is discharged from the circulation outlet 31 of the cooler 30. The refrigerant liquid 40, which is pumped from the circulation pump 10, flows into the radiator 20.

The refrigerant liquid 40, which is supplied into the radiator 20, is cooled through heat exchange with the atmosphere. As a result, the cooling apparatus 100 maintains the subcooled state of the refrigerant liquid 40. The refrigerant liquid 40, which is discharged from the radiator 20, flows into the receiving space 331 of the cooler 30 through the circulation inlet 32 of the cooler 30.

In the cooler 30, the heat, which is generated by the heat-generating device 70, is transferred to the refrigerant liquid 40 through the heat transfer member 80. As a result, the refrigerant liquid 40 near the heat transfer member 80 boils, generating bubbles of the refrigerant gas. At this time, the heat, which is generated by the heat-generating device 70, is absorbed as the latent heat of vaporization of the refrigerant liquid 40, thereby cooling the heat-generating device 70.

The bubbles of the refrigerant gas rise inside the cooling tank 33 and are retained on the lower side of the partition member 35, forming the refrigerant gas layer 332. As described above, in the case where all of the bubbles are cooled and condensed in the subcooled liquid, the refrigerant gas layer 332 will not be formed.

As described above, in the cooling apparatus 100 of the present embodiment, the heat-generating device 70, which is the cooling target, can be cooled by utilizing the latent heat of vaporization of the refrigerant liquid 40. Furthermore, in the cooling apparatus 100 of the present embodiment, since the heat transfer member 80 is employed, high cooling performance can be stably achieved even when the operating conditions change.

More specifically, as explained with reference to FIG. 7, the cooling apparatus 100 of the present embodiment uses the heat transfer member 80 that is configured to achieve the heat flux q of 300 kW/m² when the degree of superheat dT is 10 K on the boiling curve. Accordingly, the heat transfer member 80 can exhibit the high heat transfer performance regardless of the operating conditions of the cooling apparatus 100. As a result, the cooling apparatus 100 can stably exhibit the high cooling performance.

Furthermore, the inventors of the present application have confirmed that by performing the roughening treatment, that is, by forming the boiling promotion surface 84, it is possible to form the heat transfer member 80 that exhibits the high heat transfer performance, as explained with reference to FIG. 7.

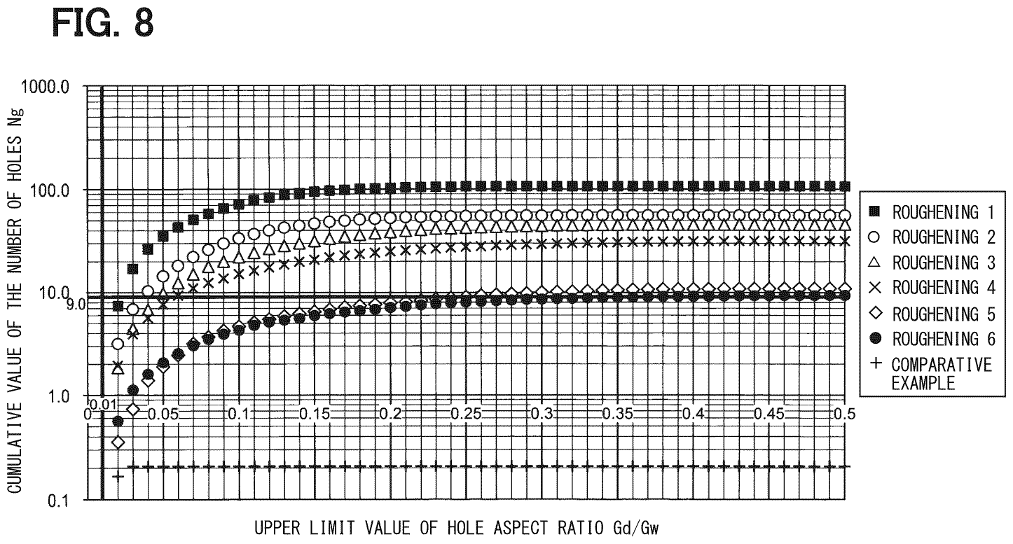

Specifically, the inventors of the present application investigated the relationship between an upper limit value of the hole aspect ratio and a cumulative value of the hole number Ng for each of six types of heat transfer members 80 that exhibit high heat transfer performance through the roughening treatment. The cumulative value of the hole number (the cumulative value of the number of holes) Ng in FIG. 8 refers to a value obtained by cumulating the hole number Ng of the holes 84c, each of which has the hole aspect ratio Gd/Gw equal to or larger than 0.01 but equal to or smaller than the upper limit value of the hole aspect ratio Gd/Gw.

As a result, as shown in FIG. 8, it has been confirmed that the heat transfer member 80 exhibits the high heat transfer performance as long as the hole aspect ratio Gd/Gw is equal to or larger than 0.01, and the hole number Ng of the holes 84c, each of which has the hole aspect ratio Gd/Gw equal to or larger than 0.01, is equal to or larger than nine (i.e., 9). Additionally, as shown in FIG. 8, when the upper limit value of the hole aspect ratio Gd/Gw becomes larger than 0.4, the cumulative value of the hole number Ng no longer changes. Therefore, the upper limit of the hole aspect ratio Gd/Gw may be set to equal to or smaller than 0.4.

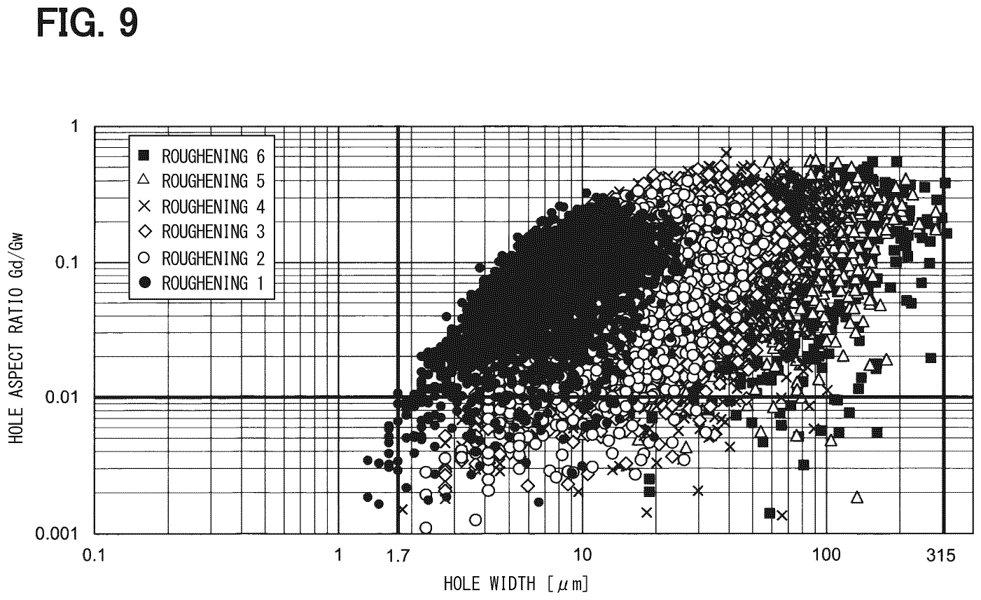

Furthermore, the inventors of the present application have investigated the distribution of the hole width Gw for each of the above-described six types of the heat transfer members 80 that exhibit the high heat transfer performance by forming the boiling promotion surface 84. As a result, as shown in FIG. 9, it has been confirmed that the heat transfer member 80 exhibits the high heat transfer performance as long as the hole width Gw is set to equal to or larger than 1.7 μm but equal to or smaller than 315 μm in the case where the hole aspect ratio Gd/Gw is equal to or larger than 0.01. Accordingly, it is possible to further reliably form the boiling promotion surface 84 that can improve the heat transfer performance.

Furthermore, in the heat transfer member 80 of the present embodiment, the finned portion 83, which serves as the surface area expansion portion, promotes the heat transfer from the heat-generating device 70 to the refrigerant. Also, since the boiling promotion surface 84 is formed on the surface that is parallel to the heat-generating body side surface 81, the boiling promotion surface 84 can be formed even when the finned portion 83 is present.

Additionally, the manufacturing method of the heat transfer member 80 of the present embodiment includes the boiling promotion surface forming step, in which the boiling promotion surface 84 is formed by the shot blasting.

Accordingly, the boiling promotion surface 84 can be formed extremely easily. Furthermore, in the boiling promotion surface forming step, since the blasting media is sprayed in the direction perpendicular to the heat-generating body side surface 81, the boiling promotion surface 84 can be easily formed not only on the surfaces, which form the tops of the finned portion 83 of the refrigerant side surface 82, but also on the surfaces, which form the bottoms of the grooves of the finned portion 83 of the refrigerant side surface 82.

The present disclosure is not limited to the above-described embodiment and may be modified in various ways as follows without departing from the spirit of the present disclosure.

(1) In the above embodiment, there is described the example where the cooling apparatus 100 is used to cool the heat-generating device 70 which is the electronic device. However, the cooling target is not limited to the electronic device. The cooling apparatus 100, which includes the heat transfer member 80 of the present embodiment, can be applied to a wide range of cooling targets that require cooling.

The cooling apparatus 100 is not limited to have the structure disclosed in the above embodiment. For example, if the refrigerant liquid 40 in a region of the receiving space 331, which is distant from the heat-generating device 70, can be maintained as the subcooled liquid, the circulation circuit 50, the circulation pump 10 and the radiator 20 may be omitted.

The heat transfer member 80 is not limited to have the structure disclosed in the above embodiment.

For example, in the above embodiment, there is described the example where the heat transfer member 80 is fixed to the heat-generating device 70 by the soldering. However, the method of fixing the heat transfer member 80 is not limited to this. For example, the heat transfer member 80 may be fixed to the heat-generating device 70 by fastening means such as bolting, in a state where a thermally conductive material in a sheet form or a grease form, having high electrical insulation and high thermal conductivity, is interposed in a gap between the heat transfer member 80 and the heat-generating device 70.

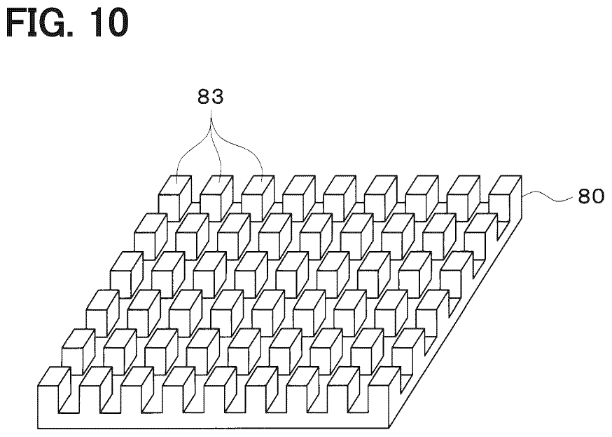

Additionally, in the above embodiment, there is described the example where the finned portion 83 is formed by the plurality of grooves extending in the up-down direction. However, the structure of the finned portion 83 is not limited this. For example, as shown in FIG. 10, the finned portion 83 may be formed by a plurality of grooves extending in the up-down direction and a plurality of grooves extending in the horizontal direction. In other words, the finned portion 83 may form so-called pin fins.

Additionally, in the above embodiment, there is described the example where the finned portion 83 is formed by the plurality of grooves, each of which has the rectangular cross-section. However, the structure of the finned portion 83 is not limited to this. For example, the finned portion 83 may be formed by a plurality of grooves, each of which has a triangular cross-section or a trapezoidal cross-section. Accordingly, the boiling promotion surface 84 can be easily formed even on side surfaces formed between adjacent fins.

(4) In the boiling promotion surface forming step of the above embodiment, there is described the example where the shot blasting is employed to form the boiling promotion surface 84. However, the method is not limited to this. If the boiling promotion surface 84, which is similar to the one described in the above embodiment, can be formed, laser processing, mechanical processing using a grinder or sander, etching, or other methods may be employed.

(5) In the above embodiment, there is described the example where the cooling tank 33 and the liquid storage tank 34 in the cooler 30 are configured as separate components (i.e., the components formed separately). The present disclosure is not limited to this. For example, the cooling tank 33 and the liquid storage tank 34 may be formed integrally in one-piece.

Although the present disclosure has been described with reference to the embodiments and the modifications, it is understood that the present disclosure is not limited to the embodiments and the modifications and structures described therein. The present disclosure also includes various variations and variations within the equivalent range. Also, various combinations and forms, as well as other combinations and forms that include only one element, more, or less, are within the scope and ideology of the present disclosure.

What is claimed is:

1. A heat transfer member to be applied to a cooling apparatus that is configured to cool a cooling target in a state where the cooling target is immersed in a refrigerant in a liquid phase while the heat transfer member is configured to promote heat transfer from the cooling target to the refrigerant, wherein:
the cooling target is an electronic device;
the refrigerant is an electrically insulating fluorinated refrigerant, a boiling point of which is equal to or lower than 100 degrees Celsius;
the refrigerant is exposed to an atmosphere; and
the heat transfer member is configured to achieve a heat flux q of 300 kW/m² or more when a degree of superheat dT of the refrigerant is 10 K, on a boiling curve having a horizontal axis representing the degree of superheat dT of the refrigerant and a vertical axis representing the heat flux q.

2. A heat transfer member to be applied to a cooling apparatus that is configured to cool a cooling target in a state where the cooling target is immersed in a refrigerant in a liquid phase while the heat transfer member is configured to promote heat transfer from the cooling target to the refrigerant, the heat transfer member comprising:
a refrigerant side surface that is configured to contact the refrigerant and has a boiling promotion surface, which is configured to promote boiling of the refrigerant, wherein:
in a roughness curve of the boiling promotion surface, each of a plurality of portions, each formed between two adjacent peaks among a plurality of peaks, is defined as a hole; a distance between the two adjacent peaks is defined as a hole width Gw; a distance between a line connecting between the two adjacent peaks and a bottom of the hole is defined as a hole depth Gd; a value, which is obtained by dividing the hole depth Gd by the hole width Gw, is defined as a hole aspect ratio Gd/Gw; and a number of holes, which are present per unit length among a plurality of holes formed respectively by the plurality of portions, is defined as a hole number Ng; and
the hole number Ng of the holes, each having the hole aspect ratio Gd/Gw equal to or larger than 0.01, present per 1 mm is equal to or larger than 9.

3. The heat transfer member according to claim 2, wherein
the hole width Gw is in a range of 315 μm≥Gw≥1.7 μm.

4. The heat transfer member according to claim 2, comprising:
a contact surface that is configured to contact the cooling target; and
a surface area expansion portion that increases a surface area of the refrigerant side surface, wherein:
the boiling promotion surface occupies 50% or more of the surface area expansion portion.
